(19) United States
(12) Patent Application Publication
(10) Pub. No.: US 2013/0271109 A1
(43) Pub. Date: Oct. 17, 2013

(54) ELECTRONIC DEVICE WITH UNIVERSAL SERIAL BUS PORT

(71) Applicant: TAO WANG, Shenzhen City (CN)

(72) Inventor: TAO WANG, Shenzhen City (CN)

(21) Appl. No.: 13/658,097

(22) Filed: Oct. 23, 2012

(30) Foreign Application Priority Data
Apr. 13, 2012 (CN) 201210107500.6

(51) Int. Cl. H03H 7/00

(52) U.S. Cl. CPC H03H 7/00
USPC 323/369

(57) ABSTRACT

An electronic device includes a USB port and a voltage dividing circuit. The USB port includes a power pin and a ground pin, the power pin is connected to a voltage port. The voltage dividing circuit is connected between the voltage port and ground and is used to divide a voltage of the voltage port to a division voltage proportional to the voltage of the voltage port. The voltage dividing circuit is also connected to the ground pin of the USB port and provides the division voltage to the ground pin.

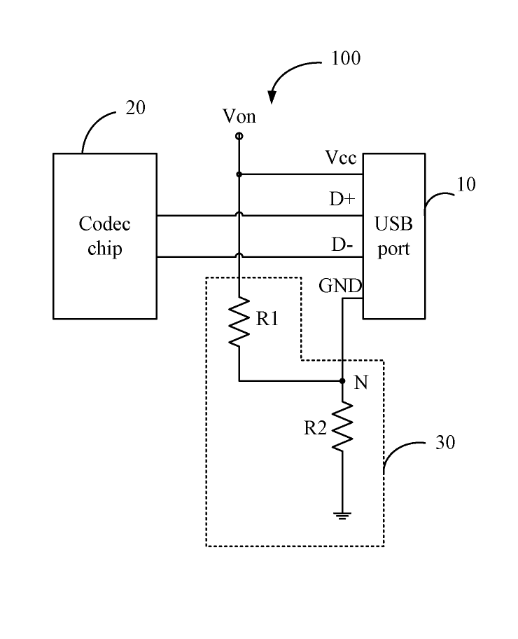

### BACKGROUND

1. Technical Field

The present disclosure relates to electronic devices, and particularly to an electronic device with a universal serial bus port.

2. Description of Related Art

Electronic devices with a universal serial bus (USB) port, such as mobile phones, tablet computers, digital photo frames, digital cameras, are widely used. When an electronic device is connected to another USB device via the USB port, and if the electronic device is shaken suddenly, a voltage of the USB port may become abnormal. For example, a voltage difference between a power pin and a ground pin of the USB port is greater than a standard value, such as about 5 volts, which would cause some problems and the USB device would become identifiable.

An electronic device with a universal serial bus port to overcome the described limitations is thus needed.

### BRIEF DESCRIPTION OF THE DRAWINGS

Many aspects of the present disclosure are better understood with reference to the following drawing. The components in the drawing are not necessarily drawn to scale, the emphasis instead being placed upon clearly illustrating the principles of the present disclosure. Moreover, in the drawing, like reference numerals designate corresponding parts throughout the view.

The FIGURE is a circuit diagram of one embodiment of an electronic device with a universal serial bus.

### DETAILED DESCRIPTION

Embodiments of the present disclosure will be described with reference to the accompanying drawing.

The FIGURE illustrates an electronic device 100 with a universal serial bus (USB) port of the embodiment. The electronic device 100 includes a USB port 10, a codec chip 20, and a voltage dividing circuit 30.

The USB port 10 includes a power pin Vcc, a positive data pin D+, a negative data pin D−, and a ground pin GND. The power pin Vcc is connected to a voltage port Von providing a voltage, and the positive data pin D+ and the negative data pin D− are respectively connected to corresponding data pins (not labeled) of the codec chip 20. The voltage port Von is a system power port of the electronic device 100, when the electronic device is connected to a battery, a power adapter, or a USB power, the power port Von would provide the voltage to power necessary components of the electronic device 100.

The voltage dividing circuit 30 is connected between the voltage port Von and ground. The voltage dividing circuit 30 is used to divide the voltage of the voltage port Von to a division voltage. Therein, the division voltage is proportional to the voltage of the voltage port Von. The voltage dividing circuit 30 is also connected to the ground pin GND of the USB port 10, and provides the division voltage to the ground pin GND.

In detail, as shown in the FIGURE, the voltage dividing circuit 30 includes a first resistor R1 and a second resistor R2 which are connected between the voltage port Von and ground in series. A connection node N of the first resistor R1 and the second resistor R2 is connected to the ground pin GND of the USB port 10. The voltage of the voltage port is divided by the first resistor R1 and the second resistor R2, and a voltage of the connection node N of the first resistor R1 and the resistor R2 is the division voltage. Assume the voltage of the voltage port Von is Von, a resistance value of the first resistor R1 is R1 and a resistance value of the second resistor R2 is R2, then the division voltage is equal to Von*R2/(R1+R2). Then the division voltage is proportional to the voltage of the voltage port Von.

Because the power pin Vcc of the USB port 10 is connected to the voltage port Von and the connection node N is connected to the ground pin GND, then the voltage of the power pin Vcc is equal to the voltage of the voltage port Von, and the voltage of the ground pin GND is equal to the division voltage. The voltage of the ground pin GND is proportional to the voltage of the power pin Vcc.

When the electronic device 100 is shaken suddenly, if the voltage of the power pin Vcc is unstable, such as the voltage of the power pin Vcc is enhanced, then the voltage of the ground pin GND would also be enhanced. A voltage difference between the power pin Vcc and the ground pin GND is decreased, thereby ensuring the electronic device 100 to maintain a normal work state when the electronic device 100 is shaken or bumped suddenly.

In one embodiment, the resistance value of the first resistor R1 is much greater than the second resistor R1, for example, the resistance value of the first resistor R1 is 400 ohm, and the resistance value of the second resistor R2 is 0.33 ohm. The voltage of the power pin Vcc is about 5 volt, and the voltage of the ground pin GND is 5*0.33/(400+0.33), which is nearly zero, thus ensuring the USB port 10 maintains the normal work state.

In one embodiment, the electronic device 100 can be a mobile phone, a digital camera, a digital photo frame, or a tablet computer.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. An electronic device comprising:
a USB port comprising a ground pin and a power pin connected to a voltage port providing a voltage and
a voltage dividing circuit connected between the voltage port and ground, configured to divide the voltage of the voltage port to a division voltage proportional to the voltage of the voltage port, wherein, the voltage dividing circuit is further connected to the ground pin of the USB port and is configured to provide the division voltage to the ground pin.

2. The electronic device according to claim 1, wherein the voltage dividing circuit comprises a first resistor and a second resistor which are connected between the voltage port and ground in series, and a connection node of the first resistor and the second resistor is connected to the ground pin of the USB port.

3. The electronic device according to claim 2, wherein the voltage of the voltage port is divided by the first resistor and the second resistor, and a voltage of the connection of the first resistor and the resistor is the division voltage.

4. The electronic device according to claim 2, wherein a resistance value of the first resistor is greater than a resistance value of the second resistor.

5. The electronic device according to claim 1, wherein the USB port further comprises a positive data pin and a negative data pin, the electronic device further comprises a codec chip, and the positive data pin and the negative data pin are connected to corresponding data pins of the codec chip.

6. The electronic device according to claim 1, wherein the electronic device is a mobile phone, a digital camera, a digital photo frame, or a tablet computer.
